(19) United States
(12) Patent Application Publication
(10) Pub. No.: US 2013/0098666 A1
(43) Pub. Date: Apr. 25, 2013

(54) RESIN COMPOSITION FOR PRINTED CIRCUIT BOARD AND PRINTED CIRCUIT BOARD INCLUDING THE SAME

(71) Applicant: Keun Yong LEE, Suwon (KR)

(72) Inventor: Keun Yong LEE, Suwon (KR)

(73) Assignee: SAMSUNG ELELCTRO-MECHANICS CO., LTD.

(21) Appl. No.: 13/341,658

(22) Filed: Dec. 30, 2011

(30) Foreign Application Priority Data
Oct. 20, 2011 (KR) 10-2011-0107328

(51) Int. Cl. H05K 1/03; C09K 19/40

(52) U.S. Cl. 174/255; 252/299.61

(57) ABSTRACT

There is provided a resin composition for a printed circuit board, including 100 parts by weight of a liquid crystal oligomer shown in a predetermined Formula; and 10 to 40 parts by weight of a rubber-modified epoxy resin.

### CROSS-REFERENCE TO RELATED APPLICATIONS

This application claims the priority of Korean Patent Application No. 10-2011-0107328 filed on Oct. 20, 2011 in the Korean Intellectual Property Office, the disclosure of which is incorporated herein by reference.

### BACKGROUND OF THE INVENTION

1. Field of the Invention

The present invention relates to a resin composition for a printed circuit board and a printed circuit board including the same.

2. Description of the Related Art

A board including an electronic circuit having a predetermined pattern printed thereon is used in various electronic products such as computers, semiconductors, display devices, or communications devices.

A printed circuit board includes a signal line for signal transmission, an insulating layer preventing a short-circuit between signal lines from occurring, and a switching element.

In accordance with the recent trend for reductions in the weight, thickness, and size of electronic devices, a highly integrated and densely printed circuit board has been required.

Therefore, the electrical, thermal, and mechanicalstability of the printed circuit board are considered to be important factors in ensuring stability and reliability in electronic devices.

### SUMMARY OF THE INVENTION

An aspect of the present invention provides a novel resin composition for a printed circuit board having improved electrical, thermal, and mechanical stability, and a printed circuit board including the same.

According to an aspect of the present invention, there is provided a resin composition for a printed circuit board, including 100 parts by weight of a liquid crystal oligomer including a structural unit of the following Formula 1, a structural unit of the following Formula 2, and a functional group of the following Formula E at at least one end thereof; and 10 to 40 parts by weight of a rubber-modified epoxy resin,

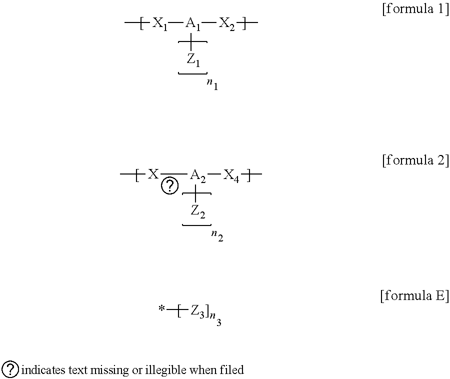

wherein X1 to X4 of Formulas 1, 2, and E are the same or different, C(═O)O, O, C(═O)NR, NR′ or CO (R and R′ are the same or different, and may be hydrogen, a substituted or unsubstituted C1 to C20 alkyl group, or a substituted or unsubstituted C6 to C30 aryl group),

Z1 to Z3 are each independently a hydroxy group, a substituted or unsubstituted C3 to C30 cycloaliphatic group, or a substituted or unsubstituted C3 to C30 hetero atom-containing cycloaliphatic group,

n1 to n3 are each independently an integer of 0 to 3, and the sum total of n1, n2, and n3 may be 1 or more, and

A1 of Formula 1 is any one of functional groups shown in the following Formulas 4-1 to 4-7,

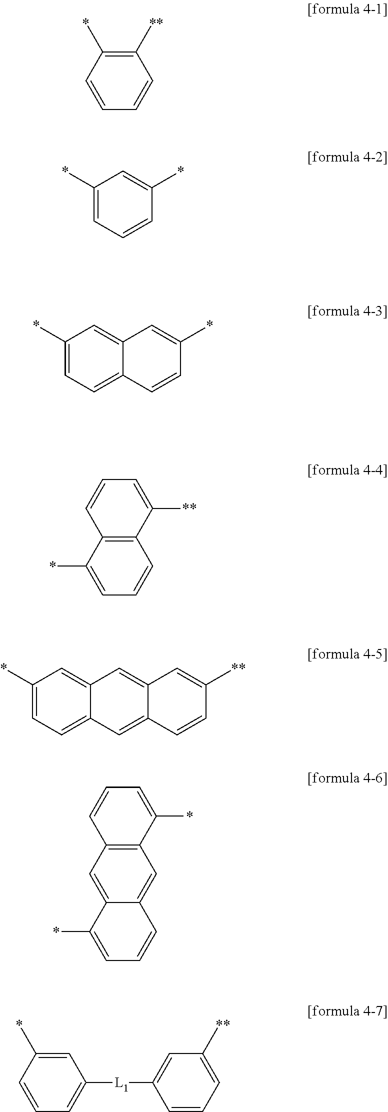

wherein L1 of Formula 4-7 is a divalent organic functional group, and at least one hydrogen atom of respective aromatic rings of Formulas 4-1 to 4-7 may be substituted with a halogen atom, a substituted or unsubstituted C1 to C20 alkyl group, a substituted or unsubstituted C1 to C20 alkoxy group, a substituted or unsubstituted C3 to C20 cycloalkyl group, a substituted or unsubstituted C6 to C30 aryl group, a substituted or unsubstituted C7 to C30 arylalkyl group, a substituted or unsubstituted C6 to C30 aryloxy group, or Z1 (Z1 is as defined in Formula 1), and

A2 of Formula 2 is a C2 to C20 alkylene group having any one of functional groups shown in the following Formulas 5-1 to 5-6 or a functional group of the following Formula 6,

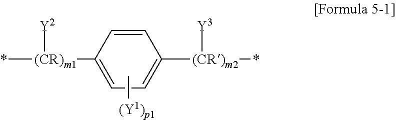

wherein Y1 to Y3 of Formula 5-1 are the same or different, and may be hydrogen, a C1 to C10 alkyl group, or a functional group of the following Formula 6, at least one of Y1 to Y3 is the functional group of the following Formula 6, p1 is an integer of 0 to 4, m1 and m2 are the same or different and an integer of 0 to 3, p1, m1, and m2 are not all simultaneously 0, and R and R′ are hydrogen or a C1 to C10 alkyl group,

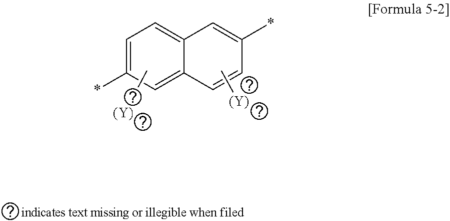

wherein Y4 and Y5 of Formula 5-2 are the same or different, and may be hydrogen, a C1 to C10 alkyl group, or a functional group of the following Formula 6, at least one of Y4 and Y5 is the functional group of the following Formula 6, and p2 and p3 are an integer of 0 to 3 and are not both simultaneously 0,

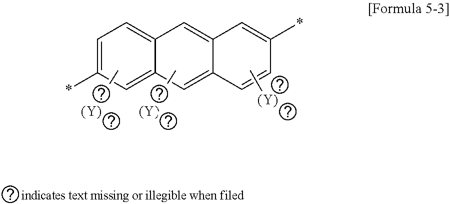

wherein Y6 to Y8 of Formula 5-3 are the same or different, and a C1 to C10 alkyl group or a functional group of the following Formula 6, at least one of Y6 to Y8 is the functional group of the following Formula 6, p4 and p6 are an integer of 0 to 3, p5 is an integer of 0 to 2, and p4, p5, and p6 are not all simultaneously 0,

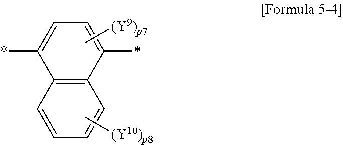

wherein Y9 and Y10 of Formula 5-4 are the same or different, and may be hydrogen, a C1 to C10 alkyl group, or a functional group of the following Formula 6, at least one of Y9 and Y10 is the functional group of the following Formula 6, and p7 and p8 are an integer of 0 to 2 and are not both simultaneously 0,

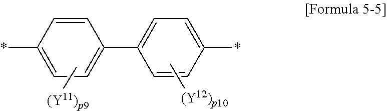

wherein Y11 and Y12 of Formula 5-5 are the same or different, and may be hydrogen, a C1 to C10 alkyl group, or a functional group of the following Formula 6, at least one of Y11 and Y12 is the functional group of the following Formula 6, and p9 and p10 are an integer of 0 to 4 and are not both simultaneously 0,

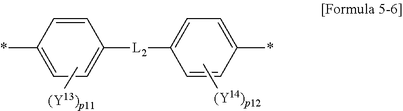

wherein Y13 and Y14 of Formula 5-6 are the same or different, and may be hydrogen, a C1 to C10 alkyl group, or a functional group of the following Formula 6, at least one of Y13 and Y14 is the functional group of the following Formula 6, p11 and p12 are an integer of 0 to 4, L2 is an ether group, a sulfide group, a ketone group, an amide group, sulfoxide, a sulfone group, an azo group, a cyanide group, a substituted or unsubstituted C1 to C20 alkylene group, a substituted or unsubstituted C2 to C20 alkenylene group, a substituted or unsubstituted C6 to C30 arylene group, a divalent organic functional group substituted or not substituted with at least one functional group of the following Formula 6, or a divalent organic functional group of the following Formulas 7-1 to 7-3, p11 and p12 are not both simultaneously 0 when L2 is not substituted with the functional group of the following Formula 6, and in Formulas 5-1 to 5-6, at least one hydrogen atom of the aromatic rings may be substituted with a halogen atom, a substituted or unsubstituted C1 to C20 alkyl group, a substituted or unsubstituted C1 to C20 alkoxy group, a substituted or unsubstituted C3 to C20 cycloalkyl group, a substituted or unsubstituted C6 to C30 aryl group, a substituted or unsubstituted C7 to C30 arylalkyl group, a substituted or unsubstituted C6 to C30 aryloxy group, or Z1 (Z1 is as defined in Formula 1),

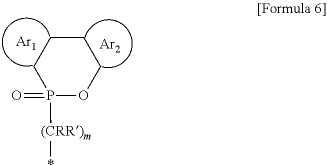

wherein Ar1 and Ar2 of Formula 6 are a C4 to C30 substituted or unsubstituted aromatic ring group, R and R′ are the same or different and may be hydrogen, a C1 to C20 alkyl group, or a C6 to C30 aryl group, and m is an integer of 0 to 3,

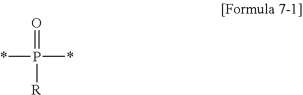

wherein R of Formula 7-1 is hydrogen, a halogen atom, a substituted or unsubstituted C1 to C20 alkyl group, a substituted or unsubstituted C1 to C20 alkoxy group, a substituted or unsubstituted C3 to C20 cycloalkyl group, a substituted or unsubstituted C6 to C30 aryl group, a substituted or unsubstituted C7 to C30 arylalkyl group, or a substituted or unsubstituted C6 to C30 aryloxy group,

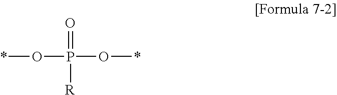

wherein R of Formula 7-2 is hydrogen, a halogen atom, a substituted or unsubstituted C1 to C20 alkyl group, a substituted or unsubstituted C1 to C20 alkoxy group, a substituted or unsubstituted C3 to C20 cycloalkyl group, a substituted or unsubstituted C6 to C30 aryl group, a substituted or unsubstituted C7 to C30 arylalkyl group, or a substituted or unsubstituted C6 to C30 aryloxy group,

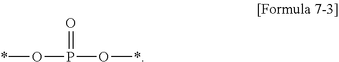

In the aspect of the present invention, the liquid crystal oligomer may have a number average molecular weight of 500 to 10,000 g/mol.

In the aspect of the present invention, the structural unit of Formula 1 may be included in an amount of 5 to 60 mol %, based on a total amount of the liquid crystal oligomer, and the structural unit of Formula 2 may be included in an amount of 40 to 95 mol %, based on the total amount of the liquid crystal oligomer.

In the aspect of the present invention, L1 of Formula 4-7 may be an ether group, a sulfide group, a ketone group, sulfoxide, a sulfone group, an azo group, a cyanide group, a substituted or unsubstituted C1 to C20 alkylene group, a substituted or unsubstituted C2 to C20 alkenylene group, or a substituted or unsubstituted C6 to C30 arylene group.

In the aspect of the present invention, L2 of Formula 5-6 may be an ether group, a sulfide group, a ketone group, an amide group, sulfoxide, a sulfone group, an azo group, a cyanide group, a substituted or unsubstituted C1 to C20 alkylene group, a substituted or unsubstituted C2 to C20 alkenylene group, a substituted or unsubstituted C6 to C30 arylene group, a divalent organic functional group substituted or not substituted with at least one functional group of the following Formula 6, or a divalent organic functional group of the following Formulas 7-1 to 7-3.

In the aspect of the present invention, Formula 6 may be shown in the following Formula 11.

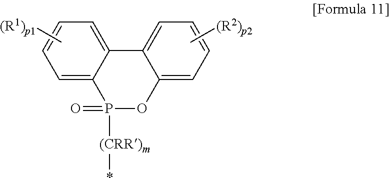

R1 and R2 of Formula 11 are the same or different, and may be hydrogen, a halogen atom, a substituted or unsubstituted C1 to C20 alkyl group, a substituted or unsubstituted C1 to C20 alkoxy group, a substituted or unsubstituted C3 to C20 cycloalkyl group, a substituted or unsubstituted C6 to C30 aryl group, a substituted or unsubstituted C7 to C30 arylalkyl group, a substituted or unsubstituted C6 to C30 aryloxy group, or Z1 (Z1 is as defined in the Formula 1), p1 and p2 are an integer of 0 to 4, R and R′ are the same or different, and may be hydrogen, a C1 to C20 alkyl group, or a C6 to C30 aryl group, and m is an integer of 0 to 3.

In the aspect of the present invention, the liquid crystal oligomer may be shown in the following Formula 12.

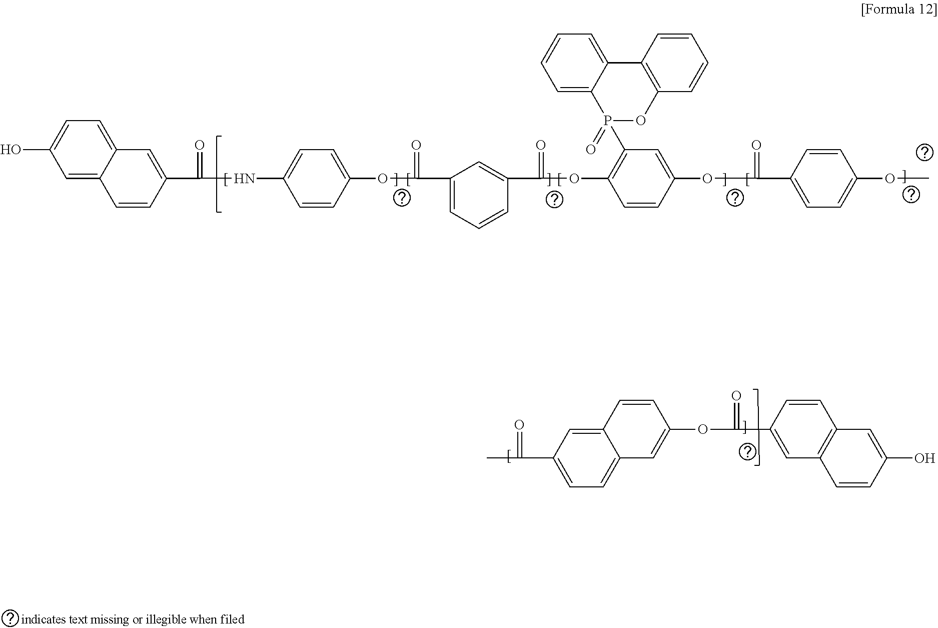

a, b, c, d and e of the Formula 12 may refer to a molar ratio of the structural unit and may be determined within the number average molecular weight of the liquid crystal oligomer.

In the aspect of the present invention, the liquid crystal oligomer may have a number average molecular weight of 2000 to 5000 g/mol.

In the aspect of the present invention, the rubber-modified epoxy resin may be shown in the following Formula 13.

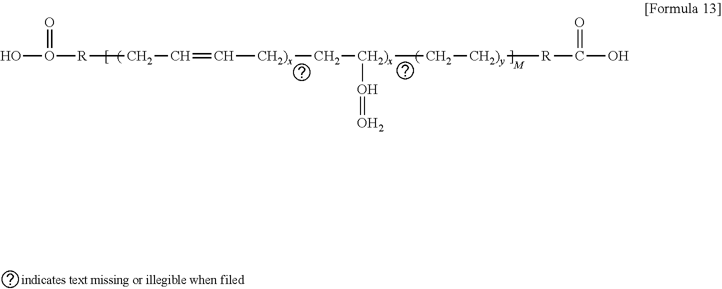

In the aspect of the present invention, Formula 13 may include at least one of amine terminated butadiene (ATBN), carboxylic acid terminated butadiene (CTBN), nitrile butadiene rubber (NBR), butadiene rubber (BR), acrylic rubber, silicone rubber, and urethane.

In the aspect of the present invention, 0.1 to 0.5 parts by weight of a curing agent may be further included.

According to another aspect of the present invention, there is provided a printed circuit board including an insulating layer; and a circuit pattern formed on the insulating layer, the insulating layer including a resin composition including 100 parts by weight of a liquid crystal oligomer including a structural unit of the following Formula 1, a structural unit of the following Formula 2, and a functional group of the following Formula E at at least one end thereof; and 10 to 40 parts by weight of a rubber-modified epoxy resin.

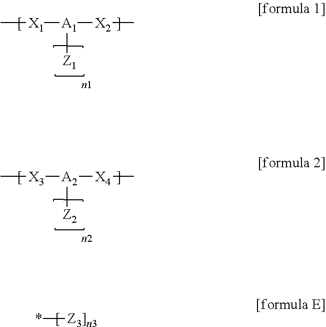

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic cross-sectional view of a printed circuit board according to an embodiment of the present invention.

### DETAILED DESCRIPTION OF THE INVENTION

Embodiments of the present invention are described with reference to the accompanying drawings below.

Many modifications and variations of the present invention are possible in light of aspects thereof, but the present invention has been described in an illustrative manner, and it is to be understood that the terminology used is intended to be in the nature of description rather than of limitation.

Embodiments of the present invention are provided so that those skilled in the art may more completely understand the present invention.

Therefore, the shape and the size of the elements may be exaggerated for clarity in the drawings, and the same reference numerals designate the same or like elements throughout the specification.

Further, parts having a similar function and performing the similar operation are designated by the same reference numerals throughout the specification.

In the specification, unless explicitly described to the contrary, the term “include” and variations thereof such as “includes” or “including”, will be understood to imply the inclusion of stated elements but not the exclusion of other elements.

Unless specifically described in the specification, the term “substituted” indicates that a hydrogen atom of a compound or a functional group may be substituted with a substituent group of a halogen atom (F, Cl, Br, and I), a hydroxy group, an alkoxy group, a nitro group, a cyano group, an amino group, an azido group, an amidino group, a hydrazino group, a hydrazono group, a carbonyl group, a carbamayl group, a thiol group, an ester group, a carboxyl group or a salt thereof, a sulfonic acid group or a salt thereof, a phosphoric acid or a salt thereof, a C1 to C20 alkyl group, a C2 to C16 alkynyl group, a C6 to C20 aryl group, a C7 to C13 arylalkyl group, a C1 to C4 oxyalkyl group, a C1 to C20 heteroalkyl group, a C3 to C20 heteroarylalkyl group, a C3 to C20 cycloalkyl group, a C3 to C15 cycloalkenyl group, a C6 to C15 cycloalkynyl group, a heterocycloalkyl group, or a combination thereof.

Unless specifically described in the specification, the term “hetero” indicates that one to three hetero atoms of N, O, S, Si, or P are present in a “hetero” ring.

Unless specifically described in the specification, the term “cycloaliphatic group” refers to a C3 to C30 cycloalkyl group, a C3 to C30 cycloalkenyl group, a C3 to C30 cycloalkynyl group, a C3 to C30 heterocycloalkyl group, a C3 to C30 heterocycloalkenyl group, a C3 to C30 heterocycloalkynyl group, or the like.

Unless specifically described in the specification, the term “aromatic ring group” refers to a functional group having a ring structure including unsaturated bonds and unshared electron pairs (lone pairs) mixed with each other and delocalization of electrons, or a resonance structure, and a C6 to C30 aryl group, a C2 to C30 heteroaryl group, and a C2 to C30 heterocycloalkenyl group.

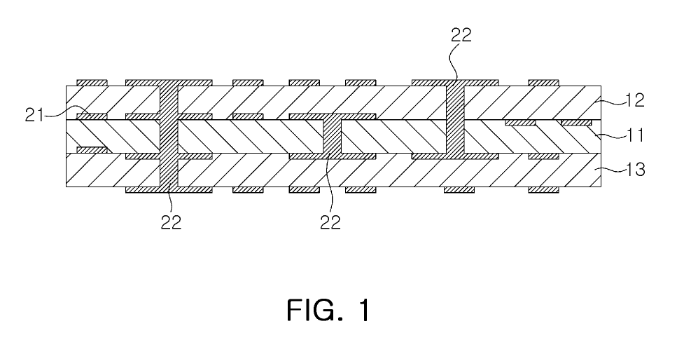

Referring to FIG. 1, a printed circuit board according to the present embodiment includes first to third insulating layers 11, 12, and 13, horizontal signal lines 21 formed as circuit patterns on one surface or both surfaces of the first to the third insulating layers 11, 12, and 13, and a via electrode 22.

For example, the first insulating layer 11 is provided as an intermediate layer, and the second insulating layer 12 and the third insulating layer 13 are layered on upper and lower surfaces of the first insulating layer 11, respectively, to form a main body of the board.

At least one horizontal signal line 21 may be formed on one surface or both surfaces of the first to the third insulating layers 11, 12, and 13, and the via electrode 22 may be perpendicularly formed through the first to the third insulating layers 11, 12, and 13 to electrically connect the horizontal signal lines 21 therethrough.

A printed circuit board having a four-layered structure is shown in the present embodiment, but the present invention is not limited thereto, and a single-layered signal line board or a multilayered signal line board may also be provided, depending on the number of insulating layers and the formed circuit pattern.

The first to the third insulating layers 11, 12, and 13 of the printed circuit board may be formed of an insulating resin composition.

In other words, the first to the third insulating layers 11, 12, and 13 may be formed of the resin composition to be specifically described according to the embodiment of the prevent invention below.

In this connection, the first to the third insulating layers 11, 12, and 13 may be formed of a prepreg including a stiffener impregnated in the insulating resin composition according to the embodiment of the present invention.

The printed circuit board including the resin composition according to the present embodiment may have predetermined electrical, thermal, and mechanical stability even in the case that the printed circuit board is reduced in weight, thickness, and size.

A detailed description is given of constitution components of the resin composition for printed circuit board according to the embodiment of the present invention and characteristics thereof below.

The resin composition according to the present embodiment may include (A), a liquid crystal oligomer (LCO) and (B), an epoxy resin, and may further include (C), a curing catalyst and a solvent.

(A) Liquid Crystal Oligomer

The liquid crystal oligomer included in the resin composition according to the present embodiment includes a structural unit of the following Formula 1, a structural unit of the following Formula 2, and a functional group of the following Formula E at at least one end thereof.

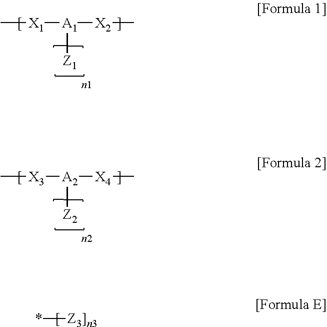

wherein X1 to X4 of Formulas 1, 2, and E may be the same or different, and may be C(═O)O, O, C(═O) NR, NR′, or CO (R and R′ are the same or different, and may be hydrogen, a substituted or unsubstituted C1 to C20 alkyl group, or a substituted or unsubstituted C6 to C30 aryl group).

Z1 to Z3 may be each independently a hydroxy group, a substituted or unsubstituted C3 to C30 cycloaliphatic group, and a substituted or unsubstituted C3 to C30 hetero atom-containing cycloaliphatic group.

n1 to n3 are each independently an integer of 0 to 3, and the sum total of n1, n2, and n3 is 1 or more.

A1 of Formula 1 maybe anyone of functional groups shown in the following Formulas 4-1 to 4-7.

In A1, both bonding groups of the aromatic ring bonded to a main chain may be present at an ortho or a meta position.

The aromatic structural unit having the kink structure may be repeatedly provided to the main chain of the liquid crystal oligomer.

That is, linearity of the main chain of the liquid crystal oligomer may be reduced due to the provided kink structure to thus reduce interaction between the main chains and crystallinity, thereby increasing solubility to the solvent.

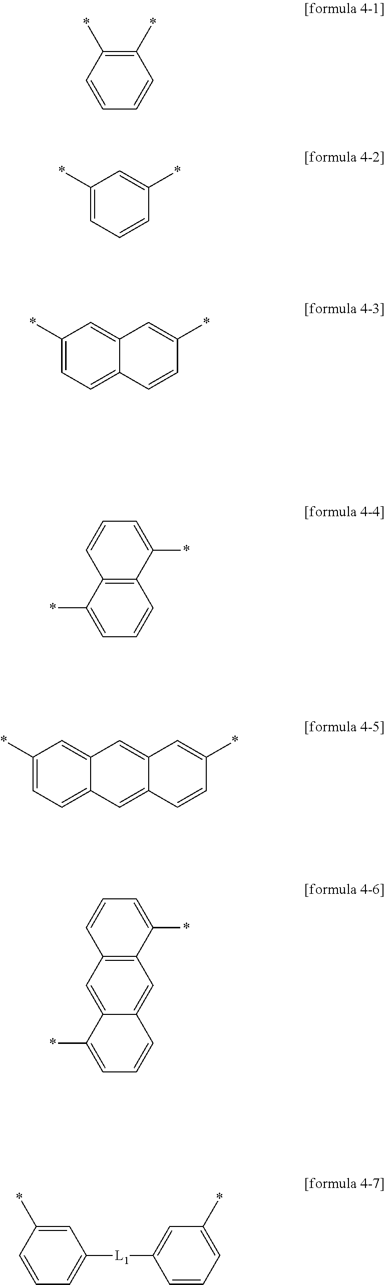

L1 of Formula 4-7 may be a divalent organic functional group, and at least one hydrogen of each of aromatic rings of Formulas 4-1 to 4-7 may be substituted with a halogen atom, a substituted or unsubstituted C1 to C20 alkyl group, a substituted or unsubstituted C1 to C20 alkoxy group, a substituted or unsubstituted C3 to C20 cycloalkyl group, a substituted or unsubstituted C6 to C30 aryl group, a substituted or unsubstituted C7 to C30 arylalkyl group, a substituted or unsubstituted C6 to C30 aryloxy group, or Z1 (Z1 is as defined in Formula 1).

A2 of Formula 2 may be a C2 to C20 alkylene group having any one of functional groups shown in the following Formulas 5-1 to 5-6 or a functional group of the following Formula 6.

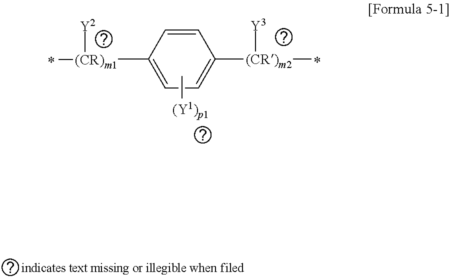

Y1 to Y3 of Formula 5-1 may be the same or different, and may be hydrogen, a C1 to C10 alkyl group, or a functional group of the following Formula 6. At least one of Y1 to Y3 may be the functional group of the following Formula 6, p1 may be an integer of 0 to 4, ml and m2 may be the same or different and an integer of 0 to 3, p1, m1, and m2 are not all simultaneously 0, and R and R′ may be hydrogen or a C1 to C10 alkyl group.

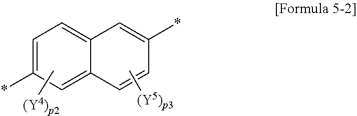

Y4 and Y5 of Formula 5-2 may be the same or different, and may be hydrogen, a C1 to C10 alkyl group, or a functional group of the following Formula 6, and at least one of Y4 and Y5 is the functional group of the following Formula 6, p2 and p3 may be an integer of 0 to 3 and are not both simultaneously 0.

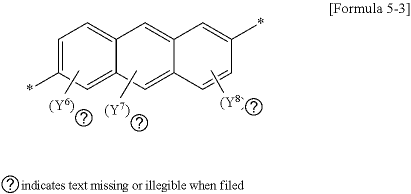

Y6 to Y8 of Formula 5-3 may be the same or different, and may be hydrogen, a C1 to C10 alkyl group, or a functional group of the following Formula 6, and at least one of Y6 to Y8 is the functional group of the following Formula 6. p4 and p6 may be an integer of 0 to 3, p5 may be an integer of 0 to 2, and p4, p5, and p6 may not all simultaneously be 0.

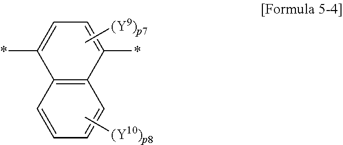

Y9 and Y10 of Formula 5-4 maybe the same or different, and may be hydrogen, a C1 to C10 alkyl group, or a functional group of the following Formula 6, and at least one of Y9 and Y10 may be the functional group of the following Formula 6. p7 and p8 may be an integer of 0 to 2 and may not both simultaneously be 0.

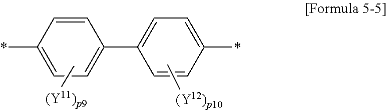

Y11 and Y12 of Formula 5-5 may be the same or different, and may be hydrogen, a C1 to C10 alkyl group, or a functional group of the following Formula 6, and at least one of Y11 and Y12 may be the functional group of the following Formula 6. p9 and p10 maybe an integer of 0 to 4 and may not both simultaneously be 0.

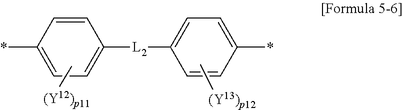

Y13 and Y14 of Formula 5-6 may be the same or different, and may be hydrogen, a C1 to C10 alkyl group, or a functional group of the following Formula 6, at least one of Y13 and Y14 maybe the functional group of the following Formula 6, p11 and p12 may be an integer of 0 to 4, and L2 may be an ether group, a sulfide group, a ketone group, an amide group, sulfoxide, a sulfone group, an azo group, a cyanide group, a substituted or unsubstituted C1 to C20 alkylene group, a substituted or unsubstituted C2 to C20 alkenylene group, a substituted or unsubstituted C6 to C30 arylene group, a divalent organic functional group substituted or not substituted with at least one functional group of the following Formula 6, or a divalent organic functional group of the following Formulas 7-1 to 7-3. Both p11 and p12 are not 0 when L2 is not substituted with the functional group of the following Formula 6.

In Formulas 5-1 to 5-6, at least one hydrogen of the respective aromatic rings maybe substituted with a halogen atom, a substituted or unsubstituted C1 to C20 alkyl group, a substituted or unsubstituted C1 to C20 alkoxy group, a substituted or unsubstituted C3 to C20 cycloalkyl group, a substituted or unsubstituted C6 to C30 aryl group, a substituted or unsubstituted C7 to C30 arylalkyl group, a substituted or unsubstituted C6 to C30 aryloxy group, or Z1 (Z1 is as defined in Formula 1).

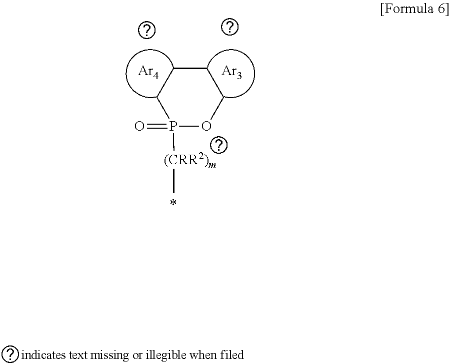

An and Ar2 of Formula 6 are a C4 to C30 substituted or unsubstituted aromatic ring group, R and R′ are the same or different and may be hydrogen, a C1 to C20 alkyl group, or a C6 to C30 aryl group, and m is an integer of 0 to 3.

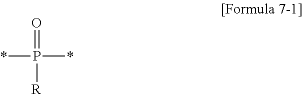

R of Formula 7-1 is hydrogen, a halogen atom, a substituted or unsubstituted C1 to C20 alkyl group, a substituted or unsubstituted C1 to C20 alkoxy group, a substituted or unsubstituted C3 to C20 cycloalkyl group, a substituted or unsubstituted C6 to C30 aryl group, a substituted or unsubstituted C7 to C30 arylalkyl group, or a substituted or unsubstituted C6 to C30 aryloxy group.

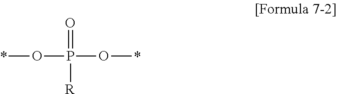

R of Formula 7-2 is hydrogen, a halogen atom, a substituted or unsubstituted C1 to C20 alkyl group, a substituted or unsubstituted C1 to C20 alkoxy group, a substituted or unsubstituted C3 to C20 cycloalkyl group, a substituted or unsubstituted C6 to C30 aryl group, a substituted or unsubstituted C7 to C30 arylalkyl group, or a substituted or unsubstituted C6 to C30 aryloxy group.

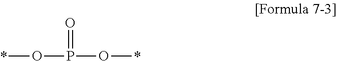

Formula 7-3 is another embodiment of the present invention and may not have R.

The liquid crystal oligomer has a number average molecular weight of 500 to 10,000 g/mol. The liquid crystal oligomer may have a predetermined crosslinking density when the number average molecular weight is in the above-mentioned range.

The structural unit of Formula 1 may be included in an amount of 5 to 60 mol % based on the total amount of the liquid crystal oligomer, and the structural unit of the Formula 2 may be included in an amount of 40 to 95 mol % based on the total amount of the liquid crystal oligomer.

When the structural unit of Formula 1 and the structural unit of Formula 2 are included in the above-mentioned amount, solubility of the liquid crystal oligomer may be increased and the insulating resin composition may be cured without a crosslinking reaction in the liquid crystal oligomer to thus improve mechanical properties.

L1 of Formula 4-7 is an ether group, a sulfide group, a ketone group, sulfoxide, a sulfone group, an azo group, a cyanide group, a substituted or unsubstituted C1 to C20 alkylene group, a substituted or unsubstituted C2 to C20 alkenylene group, or a substituted or unsubstituted C6 to C30 arylene group. Specific examples of L1 may be any one of groups shown in the following Formulas 9-1 to 9-10.

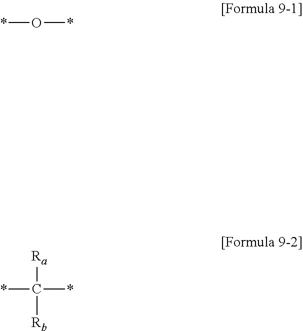

wherein Ra and Rb of Formula 9-2 are each independently hydrogen, a halogen atom, a C1 to C5 alkyl group, a C1 to C5 haloalkyl group, or Z1 (Z1 is as defined in Formula 1).

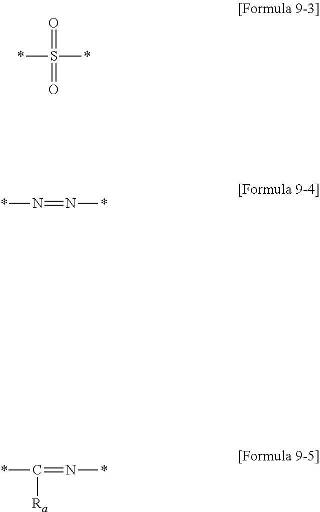

wherein Ra of Formula 9-5 is hydrogen, a halogen atom, a C1 to C5 alkyl group, a C1 to C5 haloalkyl group, or Z1 (Z1 is as defined in Formula 1).

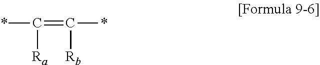

wherein Ra and Rb of Formula 9-6 are each independently hydrogen, a halogen atom, a C1 to C5 alkyl group, a C1 to C5 haloalkyl group, or Z1 (Z1 is as defined in Formula 1).

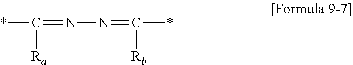

wherein Ra and Rb of Formula 9-7 are each independently hydrogen, a halogen atom, a C1 to C5 alkyl group, a C1 to C5 haloalkyl group, or Z1 (Z1 is as defined in Formula 1).

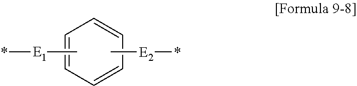

wherein E1 and E2 of Formula 9-8 may be the same or different, and may be a connection group selected from the group consisting of a single bond, an ether group, an ester group, a ketone group, a sulfide group, sulfoxide, and a sulfone group.

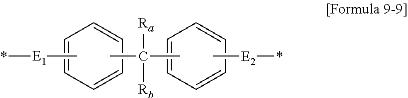

wherein Ra and Rb of Formula 9-9 are each independently hydrogen, a halogen atom, a C1 to C5 alkyl group, a C1 to C5 haloalkyl group, or Z1 (Z1 is as defined in Formula 1), and E1 and E2 may be the same or different, and may be a connection group selected from the group consisting of a single bond, an ether group, an ester group, a ketone group, a sulfide group, sulfoxide, and a sulfone group.

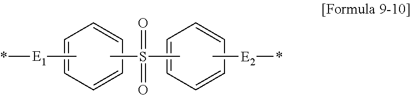

wherein E1 and E2 of Formula 9-10 are each independently a connection group selected from the group consisting of a single bond, an ether group, an ester group, a ketone group, a sulfide group, sulfoxide, and a sulfone group.

In Formulas 9-8 to 9-10, at least one hydrogen of the respective aromatic rings maybe substituted with a halogen atom, a substituted or unsubstituted C1 to C20 alkyl group, a substituted or unsubstituted Cl to C20 alkoxy group, a substituted or unsubstituted C3 to C20 cycloalkyl group, a substituted or unsubstituted C6 to C30 aryl group, a substituted or unsubstituted C7 to C30 arylalkyl group, a substituted or unsubstituted C6 to C30 aryloxy group, or Z1 (Z1 is as defined in Formula 1).

L2 of Formula 5-6 is an ether group, a sulfide group, a ketone group, an amide group, sulfoxide, a sulfone group, an azo group, a cyanide group, a substituted or unsubstituted C1 to C20 alkylene group, a substituted or unsubstituted C2 to C20 alkenylene group, a substituted or unsubstituted C6 to C30 arylene group, a divalent organic functional group substituted or not substituted with at least one functional group of the following Formula 6, or a divalent organic functional group of the following Formulas 7-1 to 7-3.

Specific examples of L2 may be any one of groups shown in Formulas 9-1 to 9-10.

In Formulas 9-2, 9-5, 9-6, 9-7, and 9-9, Ra and Rb are each independently hydrogen, a halogen atom, a C1 to C5 alkyl group, a C1 to C5 haloalkyl group, Z1 (Z1 is as defined in Formula 1), or a functional group of Formula 6, and in Formulas 9-8 to 9-10, at least one hydrogen of the respective aromatic rings may be substituted with a halogen atom, a substituted or unsubstituted C1 to C20 alkyl group, a substituted or unsubstituted C1 to C20 alkoxy group, a substituted or unsubstituted C3 to C20 cycloalkyl group, a substituted or unsubstituted C6 to C30 aryl group, a substituted or unsubstituted C7 to C30 arylalkyl group, a substituted or unsubstituted C6 to C30 aryloxy group, Z1 (Z1 is as defined in Formula 1), or a functional group of Formula 6.

As specific examples of Formula 6, the following Formula 11 may be provided.

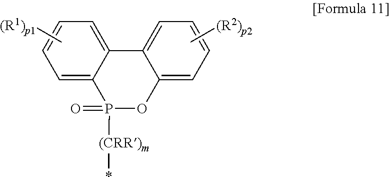

R1 and R2 of Formula 11 may be the same or different, and may be hydrogen, a halogen atom, a substituted or unsubstituted C1 to C20 alkyl group, a substituted or unsubstituted C1 to C20 alkoxy group, a substituted or unsubstituted C3 to C20 cycloalkyl group, a substituted or unsubstituted C6 to C30 aryl group, a substituted or unsubstituted C7 to C30 arylalkyl group, a substituted or unsubstituted C6 to C30 aryloxy group, or Z1 (Z1 is as defined in the Formula 1), p1 and p2 may be an integer of 0 to 4, R and R′ may be the same or different, and may be hydrogen, a C1 to C20 alkyl group, or a C6 to C30 aryl group, and m is an integer of 0 to 3.

According to the present embodiment, the liquid crystal oligomer may include a hydroxy group in one or more of a side chain and an end thereof. Therefore, the crosslinking reaction of the liquid crystal oligomer and the epoxy resin may be performed instead of the crosslinking reaction of the liquid crystal oligomers to cure the insulating resin composition.

Further, the liquid crystal oligomer may include a functional group having phosphorus in a main chain or a side chain thereof to increase flame retardancy of the insulating resin composition.

The liquid crystal oligomer according to the present embodiment is shown in the following Formula 12.

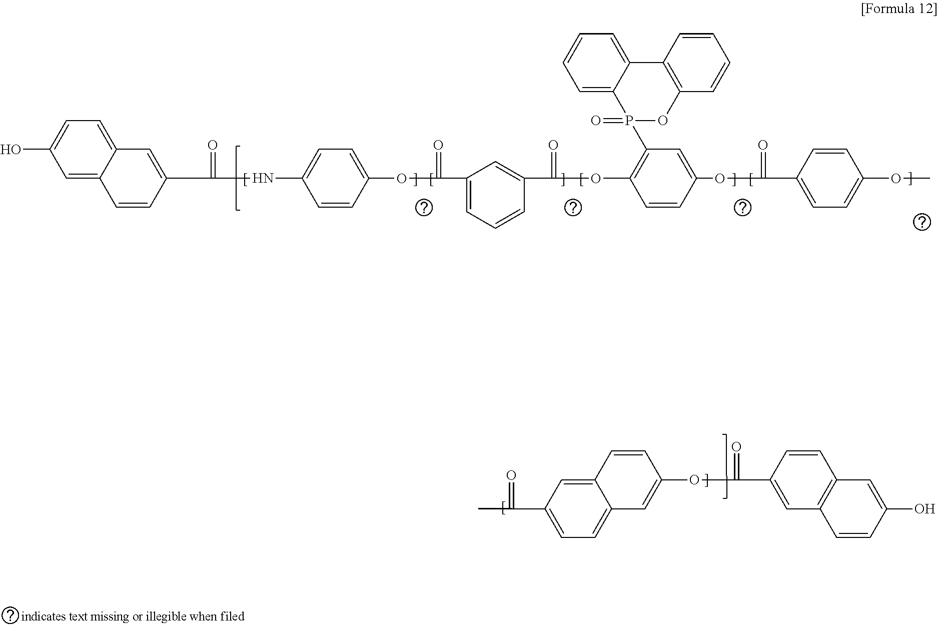

a, b, c, d and e of the Formula 12 refer to a molar ratio of the structural unit and may depend on the amount of a starting material.

The molar ratio of the structural unit of Formula 1 may be 5 to 60 mol % based on the total amount of the liquid crystal oligomer, and the molar ratio of the structural unit of Formula 2 may be 40 to 95 mol % based on the total amount of the liquid crystal oligomer.

In the present invention, the molar ratio of the structural unit of the liquid crystal oligomer is not particularly limited, but a, b, c, d and e may be determined in the above-mentioned range.

Further, the number average molecular weight Mn of the liquid crystal oligomer shown in Formula 12 may be 2000 to 5000 g/mol, and a, b, c, d and e may be determined within the range of the number average molecular weight.

The liquid crystal oligomer shown in Formula 12 may include a hydroxy group at both ends thereof and a functional group having phosphorus in a side chain thereof.

According to the present embodiment, the liquid crystal oligomer shown in Formula 12 maybe included to increase solubility. Further, the crosslinking reaction of the liquid crystal oligomer and the epoxy resin may be performed instead of the crosslinking reaction of the liquid crystal oligomers to thus cure the insulating resin composition, thereby improving mechanical properties.

(B) Epoxy Resin

The resin composition for the printed circuit board according to the present embodiment may include the epoxy resin.

Illustrating, but non-limiting examples of the epoxy resin may include a phenolic glycidyl ether type epoxy resin such as a phenol novolac type epoxy resin, a cresol novolac type epoxy resin, a naphthol-modified novolac type epoxy resin, a bisphenol A type epoxy resin, a bisphenol F type epoxy resin, a biphenyl type epoxy resin, and a triphenyl type epoxy resin; a dicyclopentadiene type epoxy resin having a dicyclopentadiene skeleton; a naphthalene type epoxy resin having a naphthalene skeleton; a dihydroxybenzopyran type epoxy resin; a glycidylamine type epoxy resin including polyamine such as diaminophenylmethane as a raw material; a triphenolmethane type epoxy resin; a tetraphenylethane type epoxy resin; or a mixture thereof.

More specific examples of the epoxy resin may include N,N,N′,N′-tetraglycidyl-4,4′-methylenebisbenzenamine, glycidyl ether type o-cresol-formaldehyde novolac (polyglycidyl ether of o-cresol-formaldehyde novolac), or a mixture thereof.

There may be a change in dimension (CTE; coefficient of thermal expansion) by heat as a main factor affecting reliability during manufacturing of the board. That is, when the CTE of the insulating layer is higher than that of the conductive layer, a crack may be generated due to a difference in the coefficient of thermal expansion of the conductive layer and the insulating layer, to reduce reliability.

A typical epoxy resin has the CTE of 70 to 100 ppm/° C., and the epoxy resin is impregnated in woven glass fibers, or a large amount of inorganic filler having a low CTE is added to the epoxy resin, to reduce the CTE in the related art.

However, when a large amount of inorganic filler is added, the CTE may be reduced, but the CTE of epoxy is high, such that a viscosity is rapidly increased due to the filler, thus hindering molding of products.

Meanwhile, when liquid oligomer is used as a main material, a characteristic of the composition becomes unstable to hinder formation of a build-up film type. Therefore, particularly, when a multilayered structure such as the insulating film of the printed circuit board is provided, it may be difficult to attach the layers.

In the present embodiment, the epoxy resin may be constituted by the rubber-modified epoxy resin to avoid the above-mentioned defect.

The rubber-modified epoxy resin may reduce a difference in the coefficient of thermal expansion of the conductive layer and the insulating layer while preventing the inorganic filler from being added in an excessively large amount to increase reliability. Further, flexibility may be provided during manufacturing of the build-up type insulating layer while excellent characteristics of liquid oligomer are ensured.

The rubber-modified epoxy resin according to the present embodiment is shown in the following Formula 13.

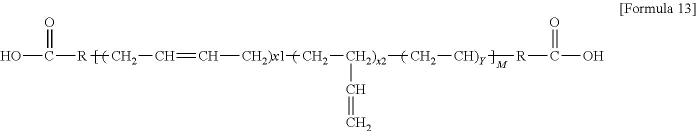

Formula 13 may include at least one of amine terminated butadiene (ATBN), carboxylic acid terminated butadiene (CTBN), nitrile butadiene rubber (NBR), butadiene rubber (BR), acrylic rubber, silicone rubber, and urethane.

For example, a typical epoxy resin may be reacted with CTBN rubber having a carboxyl group to thus produce a CTBN rubber-modified epoxy resin. The CTBN rubber having the carboxyl group includes various commercial products. A reaction ratio of the epoxy resin and the CTBN rubber may be 1000 to 5000.

In this connection, the content of the rubber-modified epoxy resin may be 10 to 40 parts by weight. This is because adhesion strength of the insulating composition may be increased when the content of the epoxy resin is in the above-mentioned range.

(C) Curing Catalyst

The insulating resin composition for the printed circuit board according to the present embodiment may include a curing catalyst.

Examples of the curing catalyst may include 2-methylimidazole, 2-phenylimidazole, 2-phenyl-4-phenylimidazole, bis(2-ethyl-4-methylimidazole), 2-phenyl-4-methyl-5-hydroxymethylimidazole, 2-phenyl-4,5-dihydroxymethylimidazole, triazine-added imidazole, methylnadic anhydride, dicyandiamide, phthalic anhydride, tetrahydrophthalic anhydride, methylbutyltetrahydrophthalic anhydride, hexahydrophthalic anhydride, methylhydrophthalic anhydride, trimethylic anhydride, pyrometallic anhydride, benzophenontetracarboxylic anhydride, or a mixture thereof. However, the curing catalyst of the present invention is not limited thereto.

The content of the curing catalyst may be 0.1 to 0.5 parts by weight. When the content of the curing catalyst is less than 0.1 parts by weight, a crosslinking reaction may be reduced, and when the content of the curing catalyst is more than 0.5 parts by weight, heat resistance may be reduced.

The resin composition for the printed circuit board according to the present embodiment may further include a solvent.

A polar non-protonic solvent may be used as the solvent, and examples of the solvent may include a halogen-based solvent such as 1-chlorobutane, chlorobenzene, 1,1-dichloroethane, 1,2-dichloroethane, chloroform, and 1,1,2,2-tetrachloroethane; an ether-based solvent such as diethyl ether, tetrahydrofuran, and 1,4-dioxane; a ketone-based solvent such as methyl ethyl ketone (MEK), acetone, and cyclohexanone; an acetate-based solvent such as propylene glycol monomethyl ether acetate (PGMEA); an ester-based solvent such as ethyl acetate; a lactone-based solvent such as γ-butyrolactone; a carbonate-based solvent such as ethylene carbonate and propylene carbonate; an amine-based solvent such as triethylamine and pyridine; a nitrile-based solvent such as acetonitrile; an amide-based solvent such as N,N′-dimethylformamide (DMF), N,N′-dimethylacetamide (DMAc), tetramethylurea, and N-methylpyrrolidone (NMP); a nitro-based solvent such as nitromethane and nitrobenzene; a sulfide-based solvent such as dimethyl sulfoxide (DMSO) and sulfolane; a phosphoric acid-based solvent such as hexamethyl phosphoric amide and tri-n-butyl phosphate; or a combination thereof. However, the solvent of the present invention is not limited thereto. The content of the solvent may be 30 to 60 parts by weight.

The resin composition for the printed circuit board according to the present embodiment may further include additives such as fillers, softeners, plasticizers, antioxidants, flame retardants, flame retardant adjuvants, lubricants, antistatic agents, coloring agents, thermal stabilizers, light stabilizers, UV absorbers, coupling agents, or antisettling agents.

As the filler, an organic filler or an inorganic filler may be used.

Illustrating, but non-limiting examples of the organic filler may include epoxy resin powder, melamine resin powder, urea resin powder, benzoguanamine resin powder, and styrene resin.

Illustrating, but non-limiting examples of the inorganic filler may include natural silica, fused silica, amorphous type silica, hollow silica, aluminum hydroxide, boehmite, magnesium hydroxide, molybdenum oxide, zinc molybdate, zinc borate, zinc stannate, aluminum borate, potassium titanate, magnesium sulfate, silicon carbide, zinc oxide, silicon nitride, silicon oxide, aluminum titanate, barium titanate, barium strontium titanate, aluminum oxide, alumina, clay, kaolin, talc, calcined clay, calcined kaolin, calcined talc, mica, short glass fibers, and the like.

The organic filler and the inorganic filler may be used alone or in combination to reduce the coefficient of thermal expansion of the liquid oligomer.

Illustrating, but non-limiting examples of the plasticizer may include polyethylene glycol, polyamide oligomer, ethylenebisstearamide, phthalate ester, polystyrene oligomer, liquid paraffin, polyethylene wax, and silicon oil. The examples of the plasticizer may be used alone or in combination.

Illustrating, but non-limiting examples of the antioxidant may include a phosphorus-containing antioxidant, a phenol-based antioxidant, and a sulfur-containing antioxidant. The examples of the antioxidant may be used alone or in combination.

The above-mentioned constituent components may be blended using various methods such as mixing at normal temperature or melt mixing to produce the resin composition for the printed circuit board according to the present embodiment.

### EXAMPLE

### Synthetic Example: Production of the Hydroxy Group-End Capped Phosphorus-Containing Liquid Crystal Oligomer

1364.13 g (12.5 mol) of 4-aminophenol, 2907.28 g (17.5 mol) of the isophthalic acid, 1609.10 g (11.65 mol) of the 4-hydroxybenzoic acid, 1486.62 g (7.9 mol) of the 6-hydroxy-2-naphtoic acid, 2432.03 g (7.5 mol) of 2-(6-oxido-6H-dibenz[c,e][1,2]oxaphosphorine-6-yl)-1,4-benz enediol (DOPO-HQ), 705.68 g (3.75 mol) of the 6-hydroxy-2-naphtoic acid for end capping, and 6687.41 g (65.505 mol) of acetic anhydride were added to the 20 L glass reactor.

The mechanical agitator, the nitrogen supply tube, the thermocouple, and the reflux condenser were provided in the sealed glass reactor.

After the inside of the reactor was sufficiently substituted using nitrogen gas, the temperature of the reactor was increased to 140° C. under a nitrogen gas flow, and a reflux was performed for 3 hours while the temperature of the reactor was maintained at 140° C.

Subsequently, the acetic acid as the byproduct during the reaction and unreacted acetic anhydride were removed, and the temperature was increased to 250° C.

After 1411.35 g (7.5 mol) of 6-hydroxy-2-naphthoic acid was added at 250° C., the temperature was increased from 250° C. to 300° C., and the reaction was performed for 2 to 4 hours to obtain the liquid crystal oligomer shown in the following Formula 12-1.

The liquid crystal oligomer had the number average molecular weight (Mn) of 4100 g/mol.

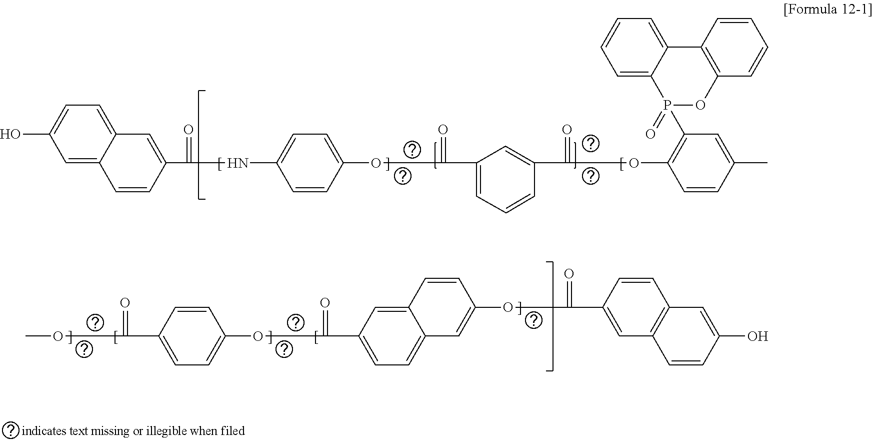

a, b, c, d, and e of Formula 12-1 may refer to a molar ratio of the repeating unit and may depend on the amount of a starting material.

Comparison of Films for Forming the Insulating Layer

### EXAMPLE

22.0 to 33.0 g of the liquid crystal oligomer, 11 to 17 g of Araldite MY-721 (Huntsmann Internatinoal LLC), 1 to 5 g of the rubber-modified epoxy resin, and 0.22 to 0.33 g of dicyandiamide as the curing catalyst were added to 45.0 g of N,N′-dimethylacetamide (DMAc) to produce the mixture solution.

The mixture solution was applied on the glass plate, heated on the hot plate for about 20 min, and heat treated in the vacuum oven to be cured.

The glass plate coated with the cured film is immersed in the 2 wt % hydrofluoric acid aqueous solution for about 1 hour to peel the cured film, the resulting film was cut in a predetermined size and heat treated at about 150° C. for about 60 min, and the coefficient of thermal expansion was measured using the thermal warpage analysis.

The coefficient of thermal expansion was measured in a nitrogen atmosphere, and in this connection the temperature was measured while being increased at a rate of 5° C./min.

### COMPARATIVE EXAMPLE

The same procedure as the example was repeated to produce the film for forming the insulating layer, except that 16.5 to 33.0 g of the thermally curable liquid crystal oligomer obtained in the synthetic example, 11.0 g of 4,4′-diphenylmethane bismaleimide (BMI-1000), 11.0 g of

Araldite MY-721 (Huntsmann Internatinoal LLC), and 0.11 g of dicyandiamide (DICY) as the curing catalyst were added to 45 g of N-methylpyrrolidone (NMP) to produce the mixture solution.

[Evaluation]

The films produced in the example and the comparative example were evaluated using the following methods, and the results are described in the following Table 1.

1. Evaluation of the Thermal Property of the Film

The glass transition temperature of the samples of the films produced in the example and the comparative example was measured using the dynamic mechanical analyzer (DMA, TA Instruments DMA Q800).

The coefficient of thermal expansion (CTE) was measured using the thermomechanical analyzer (TMA, TA Instruments TMA Q400) in a nitrogen atmosphere while the temperature was increased to a rate of 1000° C./min.

2. Evaluation of the Peel Strength of the Copper Clad of the Film

The copper clad having the width of 1 cm was peeled from the surface of the copper clad laminate, and the peel strength of the copper clad to the insulating layer was measured using the tensile strength measuring device (90° Peel Test, Crosshead speed: 50 mm/min).

3. Evaluation of Chemical Resistance of the Film

After the film was immersed in the 30 wt % potassium hydroxide aqueous solution at 80° C. for 15 min, a change in appearance of the film was observed, and wt % of the lost amount (wt % of the corrosion amount) was calculated to evaluate chemical resistance.

4. Evaluation of the Dielectric Property of the Film

The dielectric constant of the film was measured using the RF impedance analyzer at 1 GHz.

TABLE 1

| | Comparative | |
|---|---|---|
| | example | Example |
| Glass transition temperature (° C.) | 210 | 230 |
| Coefficient of thermal expansion (ppm/° C.) | 49 | 38 |
| Peel strength (kgf/cm) | 0.9 | 1.2 |
| Chemical resistance (corrosion amount, wt %) | 0.3 | 0.05 |
| Dielectric property (1 GHz) | 3.0 | 2.9 |

Referring to Table 1, the film produced using the resin composition according to the present embodiment in the example had the relatively low coefficient of thermal expansion (CTE), and increased peel strength, chemical resistance, and dielectric property.

On the contrary, the film produced using the resin composition in the related art in the comparative example had the higher coefficient of thermal expansion and the lower peel strength, chemical resistance, and dielectric property as compared to those of the example.

It is deemed that the thermally curable liquid crystal oligomers were used in the comparative example, but the crosslinking reaction was not efficiently performed therebetween and 4,4′-diphenylmethane bismaleimide (BMI-1000) was included as the crosslinking agent to significantly reduce the chemical resistance.

Therefore, the film having the low coefficient of thermal expansion and excellent stripping strength, chemical resistance, and dielectric property according to the example may be applied to a ultra-highly dense printed circuit board.

As set forth above, according to embodiments of the present invention, a lightweight, slim, and small-sized printed circuit board having the same or higher level of electric, thermal, and mechanical properties as compared to a printed circuit board in the related art may be provided.

The present invention is not limited to the embodiments and the accompanying drawings, but to the accompanying claims.

While the present invention has been shown and described in connection with the embodiments, it will be apparent to those skilled in the art that modifications and variations can be made without departing from the spirit and scope of the invention as defined by the appended claims.

What is claimed is:

1. A resin composition for a printed circuit board, comprising:
100 parts by weight of a liquid crystal oligomer including a structural unit of the following Formula 1, a structural unit of the following Formula 2, and a functional group of the following Formula E at at least one end thereof; and
10 to 40 parts by weight of a rubber-modified epoxy resin, 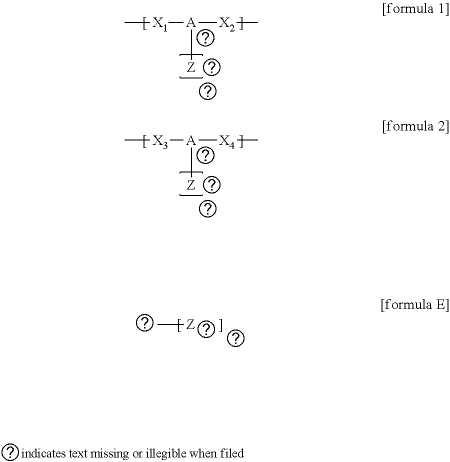
wherein X1 to X4 of Formulas 1, 2, and E are the same or different, and C(═O)O, O, C(═O) NR, NR′, or CO (R and R′ are the same or different, and are hydrogen, a substituted or unsubstituted C1 to C20 alkyl group, or a substituted or unsubstituted C6 to C30 aryl group),
Z1 to Z3 are each independently a hydroxy group, a substituted or unsubstituted C3 to C30 cycloaliphatic group, or a substituted or unsubstituted C3 to C30 hetero atom-containing cycloaliphatic group,
n1 to n3 are each independently an integer of 0 to 3, and a sum total of n1, n2, and n3 is 1 or more, and
A1 of Formula 1 is any one of functional groups shown in the following Formulas 4-1 to 4-7, 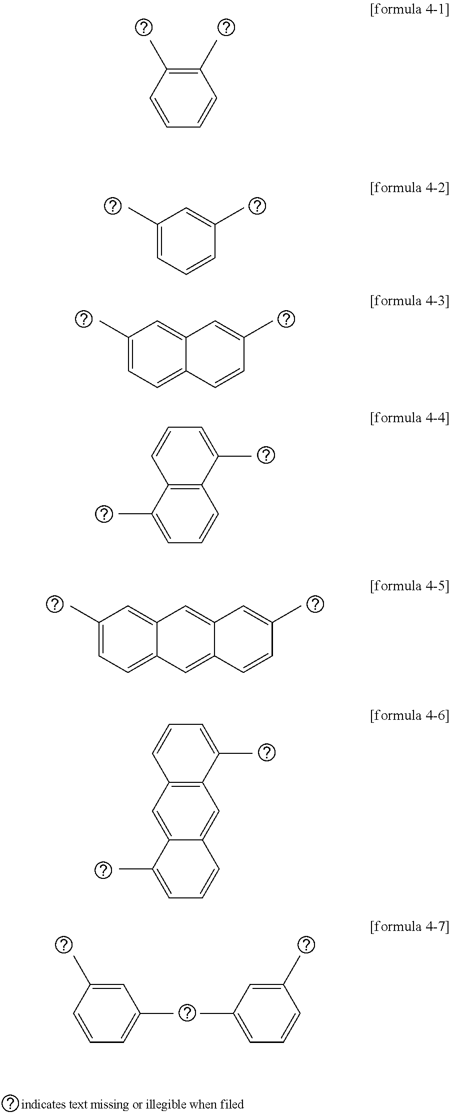
wherein L1 of Formula 4-7 is a divalent organic functional group, and at least one hydrogen of respective aromatic rings of Formulas 4-1 to 4-7 is substituted with a halogen atom, a substituted or unsubstituted C1 to C20 alkyl group, a substituted or unsubstituted C1 to C20 alkoxy group, a substituted or unsubstituted C3 to C20 cycloalkyl group, a substituted or unsubstituted C6 to C30 aryl group, a substituted or unsubstituted C7 to C30 arylalkyl group, a substituted or unsubstituted C6 to C30 aryloxy group, or Z1 (Z1 is as defined in Formula 1), and
A2 of Formula 2 is a C2 to C20 alkylene group having any one of functional groups shown in the following Formulas 5-1 to 5-6 or a functional group of the following Formula 6, 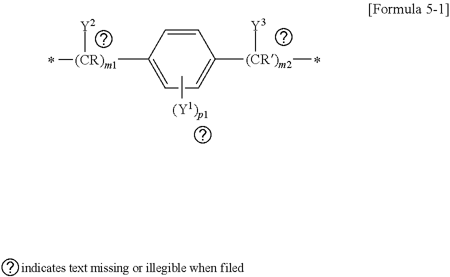
wherein Y1 to Y3 of Formula 5-1 are the same or different, and are hydrogen, a C1 to C10 alkyl group, or a functional group of the following Formula 6, at least one of Y1 to Y3 is the functional group of the following Formula 6, p1 is an integer of 0 to 4, ml and m2 are the same or different and an integer of 0 to 3, p1, ml, and m2 are not all simultaneously 0, and R and R′ are hydrogen or a C1 to C10 alkyl group, 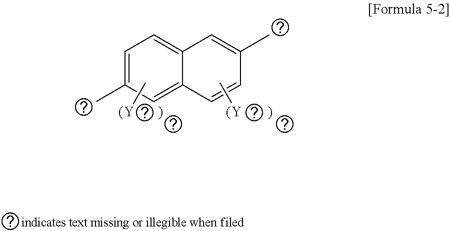
wherein Y4 and Y5 of Formula 5-2 are the same or different, and are hydrogen, a C1 to C10 alkyl group, or a functional group of the following Formula 6, at least one of Y4 and Y5 is the functional group of the following Formula 6, and p2 and p3 are an integer of 0 to 3 and are not both simultaneously 0, 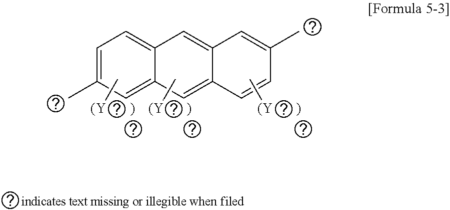
wherein Y6 to Y8 of Formula 5-3 are the same or different, and a C1 to C10 alkyl group or a functional group of the following Formula 6, at least one of Y6 to Y8 is the functional group of the following Formula 6, p4 and p6 are an integer of 0 to 3, p5 is an integer of 0 to 2, and p4, p5, and p6 are not all simultaneously 0, 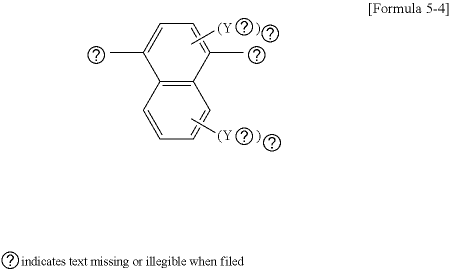
wherein Y9 and Y10 of Formula 5-4 are the same or different, and are hydrogen, a C1 to C10 alkyl group, or a functional group of the following Formula 6, at least one of Y9 and Y10 is the functional group of the following Formula 6, and p7 and p8 are an integer of 0 to 2 and are not both simultaneously 0, 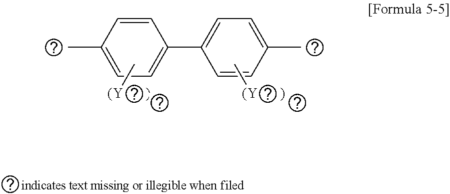
wherein Y11 and Y12 of Formula 5-5 are the same or different, and are hydrogen, a C1 to C10 alkyl group, or a functional group of the following Formula 6, at least one of Y11 and Y12 is the functional group of the following Formula 6, and p9 and p10 are an integer of 0 to 4 and are not both simultaneously 0, 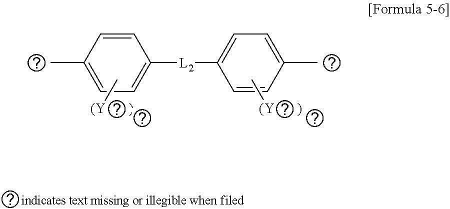
wherein Y13 and Y14 of Formula 5-6 are the same or different, and are hydrogen, a C1 to C10 alkyl group, or a functional group of the following Formula 6, at least one of Y13 and Y14 is the functional group of the following Formula 6, p11 and p12 are an integer of 0 to 4, L2 is an ether group, a sulfide group, a ketone group, an amide group, sulfoxide, a sulfone group, an azo group, a cyanide group, a substituted or unsubstituted C1 to C20 alkylene group, a substituted or unsubstituted C2 to C20 alkenylene group, a substituted or unsubstituted C6 to C30 arylene group, a divalent organic functional group substituted or not substituted with at least one functional group of the following Formula 6, or a divalent organic functional group of the following Formulas 7-1 to 7-3, p11 and p12 are not both simultaneously 0 when L2 is not substituted with the functional group of the following Formula 6, and in Formulas 5-1 to 5-6, at least one hydrogen atom of the aromatic rings is substituted with a halogen atom, a substituted or unsubstituted C1 to C20 alkyl group, a substituted or unsubstituted C1 to C20 alkoxy group, a substituted or unsubstituted C3 to C20 cycloalkyl group, a substituted or unsubstituted C6 to C30 aryl group, a substituted or unsubstituted C7 to C30 arylalkyl group, a substituted or unsubstituted C6 to C30 aryloxy group, or Z1 (Z1 is as defined in Formula 1), 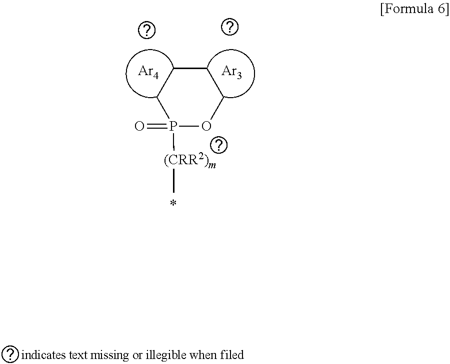
wherein Ar1 and Ar2 of Formula 6 are a C4 to C30 substituted or unsubstituted aromatic ring group, R and R′ are the same or different and are hydrogen, a C1 to C20 alkyl group, or a C6 to C30 aryl group, and m is an integer of 0 to 3, 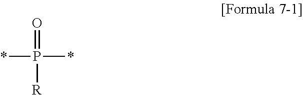
wherein R of Formula 7-1 is hydrogen, a halogen atom, a substituted or unsubstituted C1 to C20 alkyl group, a substituted or unsubstituted C1 to C20 alkoxy group, a substituted or unsubstituted C3 to C20 cycloalkyl group, a substituted or unsubstituted C6 to C30 aryl group, a substituted or unsubstituted C7 to C30 arylalkyl group, or a substituted or unsubstituted C6 to C30 aryloxy group, 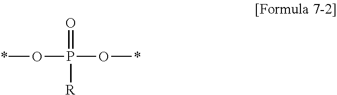
wherein R of Formula 7-2 is hydrogen, a halogen atom, a substituted or unsubstituted C1 to C20 alkyl group, a substituted or unsubstituted C1 to C20 alkoxy group, a substituted or unsubstituted C3 to C20 cycloalkyl group, a substituted or unsubstituted C6 to C30 aryl group, a substituted or unsubstituted C7 to C30 arylalkyl group, or a substituted or unsubstituted C6 to C30 aryloxy group

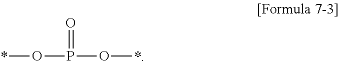

2. The resin composition of claim 1, wherein the liquid crystal oligomer has a number average molecular weight of 500 to 10,000 g/mol.

3. The resin composition of claim 1, wherein the structural unit of the Formula 1 is included in an amount of 5 to 60 mol %, based on a total amount of the liquid crystal oligomer, and the structural unit of the Formula 2 is included in an amount of 40 to 95 mol % based on the total amount of the liquid crystal oligomer.

4. The resin composition of claim 1, wherein L1 of the Formula 4-7 is an ether group, a sulfide group, a ketone group, sulfoxide, a sulfone group, an azo group, a cyanide group, a substituted or unsubstituted C1 to C20 alkylene group, a substituted or unsubstituted C2 to C20 alkenylene group, or a substituted or unsubstituted C6 to C30 arylene group.

5. The resin composition of claim 1, wherein L2 of Formula 5-6 is an ether group, a sulfide group, a ketone group, an amide group, sulfoxide, a sulfone group, an azo group, a cyanide group, a substituted or unsubstituted C1 to C20 alkylene group, a substituted or unsubstituted C2 to C20 alkenylene group, a substituted or unsubstituted C6 to C30 arylene group, a divalent organic functional group substituted or not substituted with at least one functional group of the following Formula 6, or a divalent organic functional group of the following Formulas 7-1 to 7-3.

6. The resin composition of claim 1, wherein the Formula 6 is shown in the following Formula 11: 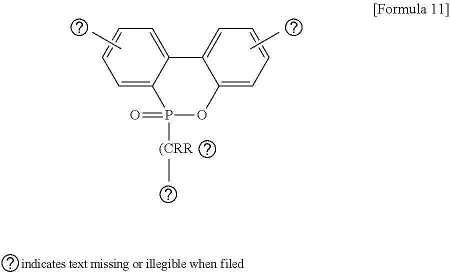
wherein R1 and R2 of Formula 11 are the same or different, and are hydrogen, a halogen atom, a substituted or unsubstituted C1 to C20 alkyl group, a substituted or unsubstituted C1 to C20 alkoxy group, a substituted or unsubstituted C3 to C20 cycloalkyl group, a substituted or unsubstituted C6 to C30 aryl group, a substituted or unsubstituted C7 to C30 arylalkyl group, a substituted or unsubstituted C6 to C30 aryloxy group, or Z1 (Z1 is as defined in the Formula 1), p1 and p2 are an integer of 0 to 4, Rand R′ are the same or different, and are hydrogen, a C1 to C20 alkyl group, or a C6 to C30 aryl group, and m is an integer of 0 to 3.

7. The resin composition of claim 1, wherein the liquid crystal oligomer is shown in the following Formula 12: 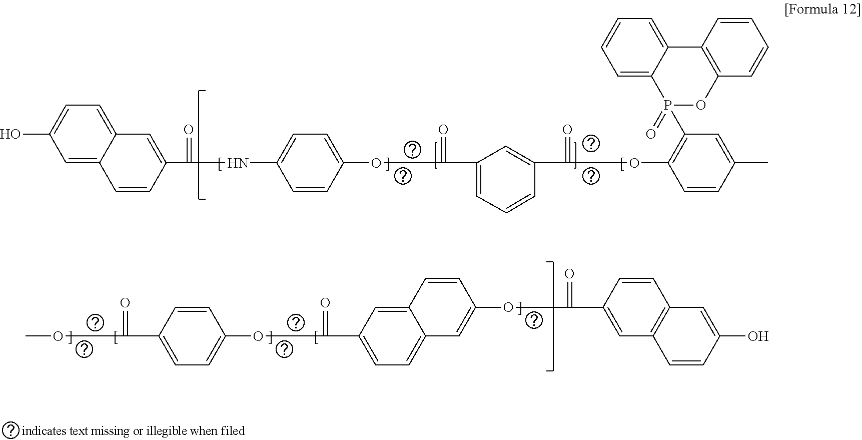
wherein a, b, c, d and e of the Formula 12 refer to a molar ratio of the structural unit and are determined within the number average molecular weight of the liquid crystal oligomer.

8. The resin composition of claim 7, wherein the liquid crystal oligomer has the number average molecular weight of 2000 to 5000 g/mol.

9. The resin composition of claim 1, wherein the rubber-modified epoxy resin is shown in the following Formula 13:

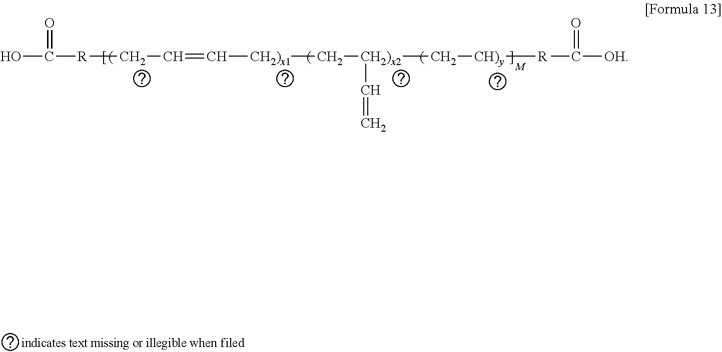

10. The resin composition of claim 9, wherein the Formula 13 includes at least one of amine terminated butadiene (ATBN), carboxylic acid terminated butadiene (CTBN), nitrile butadiene rubber (NBR), butadiene rubber (BR), acrylic rubber, silicone rubber, and urethane.

11. The resin composition of claim 1, further comprising 0.1 to 0.5 parts by weight of a curing agent.

12. A printed circuit board comprising:
an insulating layer; and
a circuit pattern formed on the insulating layer, the insulating layer including a resin composition including 100 parts by weight of a liquid crystal oligomer including a structural unit of the following Formula 1, a structural unit of the following Formula 2, and a functional group of the following Formula E at at least one end thereof; and 10 to 40 parts by weight of a rubber-modified epoxy resin: [chemical structure]
